(19) United States
(12) Patent Application Publication
(10) Pub. No.: US 2025/0178847 A1
(43) Pub. Date: Jun. 5, 2025

(54) Gripper Head, Device, and Method for Handling and Varying the Spacing of Electronic Components Arranged in a Matrix Structure

(71) Applicant: Besi Netherlands B.V., Duiven (NL)

(72) Inventor: Mark Hermans, Arnhem (NL)

(21) Appl. No.: 18/840,752

(22) PCT Filed: Feb. 21, 2023
(86) PCT No.: PCT/NL2023/050082

§ 371 Date: Aug. 22, 2024

(30) Foreign Application Priority Data
Feb. 23, 2022 (NL) 2031053

(51) Int. Cl. B65G 47/91; H01L 21/67

(52) U.S. Cl. CPC B65G 47/918; H01L 21/67144

(57) ABSTRACT

A gripper head for handling and varying the spacing of electronic components arranged in a matrix structure, including multiple grippers arranged in a matrix orientation of X rows and Y columns of grippers; and individually controllable displacement drives acting between adjoining gripper rows and between adjoining gripper columns. A device and a method for handling and varying the spacing of electronic components.

### CROSS-REFERENCE TO RELATED APPLICATIONS

This application is the United States national phase of International Application No. PCT/NL2023/050082 filed Feb. 21, 2023, and claims priority to The Netherlands Patent Application No. 2031053 filed Feb. 23, 2022, the disclosures of which are hereby incorporated by reference in their entireties.

### BACKGROUND OF THE INVENTION

### Field of the Invention

The present invention relates to a gripper head for handling and varying the spacing of electronic components arranged in a matrix structure as well as to a device for handling and varying the spacing of electronic components arranged in a matrix structure. The invention also relates to a method for handling and varying the spacing of electronic components arranged in a matrix structure with such a gripper head.

The regrouping of electronic components supplied in a matrix structure, such as for instance in the production of semiconductors, is known. During production of for instance semiconductors, semi-finished components and/or finished semiconductors will pass different successive processes which may or may not be performed in different processing stations. The (semi-finished) semiconductors may be transported between different locations, for which transportation for instance standardized carriers may be used. Different processing stations require and deliver electronic components in a matrix structures, though certainly not always in matrixes with identical numbers, identical spacings and/or configurations. It is thus possible that the mutual spacing, the relative orientation and/or—if batchwise production steps are involved—the group size in an initial matrix structure does not correspond to the orientation of the electronic components in which successive processing stations or successive process steps are performed.

In a matrix structured electronic components are grouped in rows and columns, wherein the direction of the rows is normally substantially perpendicularly to the direction of the rows of the matrix structure, however also a different mutual angular ratio is conceivable. The electronic components are normally supported by a carrier, usually, though not necessarily, a flat carrier, for instance a carrier in the form of a carrier plate optionally provided with individual product holders, a carrier with a plurality of parallel guide channels for electronic components, a conveyor belt or any other type of carrier accessible from the top side.

During transfer of the electronic components from one carrier to another carrier the pitch between the components and/or the number of rows and columns may be modified. As an example; in case of smaller electronic components (envisage here for instance electronic components with a maximum upper surface area of only a few mm²) it may be desirable to reduce the number of rows of the matrix arrangement in which the electronic components are supplied, for instance shortly after separation of the electronic components, so as to thus make possible spacing apart of the rows of electronic components without this resulting in a very considerable increase in the width of the matrix arrangement of electronic components to be discharged.

The matrix geometry of the electronic components may be changed by individual engagement of the electronic components by a manipulator with a gripper head having plural grippers (e.g. vacuum cups or mechanical grippers) the relative orientation of which individual grippers corresponds to the orientation of the group of electronic components to be engaged. Before the electronic components held by the grippers are discarded the relative position of the individual grippers may be changed to fit (or partially fit) the matrix geometry required in the subsequent processing step.

### Description of Related Art

An example of a method and device for modifying the relative orientation of electronic components supplied in a matrix form is described in, among others, the international patent application WO 07011218 of the present applicant. The method and device described in this publication function adequately, although the flexibility in efficient regrouping of electronic components has limitations.

### SUMMARY OF THE INVENTION

The object of the present invention is to provide a gripper head, a device and a method with greater flexibility, to be realised with a relative simple gripper head, than the prior art in respect of handling and modifying the relative orientation of matrix structure oriented electronic components.

The present invention provides for this purpose a gripper head for handling and varying the spacing of electronic components arranged in a matrix structure, comprising: multiple grippers arranged in a matrix orientation of X rows of grippers, wherein X≥2, and Y columns of grippers, wherein Y≥3; and separate displacement drives between all the adjoining gripper rows and between all the adjoining gripper columns, in particular for varying the distance between adjoining gripper rows and adjoining gripper columns; wherein the displacement drives are individually and separately controllable enabling to vary the distances between all the adjoining rows and/or columns of grippers. With such a gripper head the matrix orientation may have a relatively simple construction and only a limited number of drives are required to provide the required structural flexibility in the tool. Preferably displacement drives are acting between all adjoining gripper rows and/or displacement drives acting between all adjoining gripper columns which results in only the requirement of a single displacement drive between adjoining gripper columns and/or adjoining gripper rows. In this respect the word “between” the adjoining gripper columns and/or adjoining gripper rows is to be understood as enabling the displacement between the columns and/or rows, which may be realised by the displacement drives being located between adjoining gripper columns and/or adjoining gripper rows but it may also be realised with the displacement drives being located on a distance of the gripper columns and gripper rows but being connected to the columns and/or rows with for instance extensions/projections/lugs. As the displacement drives are individually controllable the intermediate distances between plural rows and/or between plural columns may vary; which makes the grippe head very flexible in use. For instance when a matrix of electronic components has to be placed on two carriers (thus with the transition of the carriers to be incorporated in the geometry of the matrix of electronic components) this enables to vary the spacing there where the carriers are bordering).

In a preferred embodiment the grippers in each row are moveable mounted on individual row guides and the grippers in each column are moveable mounted on individual column guides, and in such embodiment the displacement drives may be attached between adjoining row guides and between adjoining columns guides. As the rows and/or the columns of the grippers are attached on an individual (and dedicated) guide the groups and/or rows of grippers are linked so that a single displacement drive connected with two adjoining guide relatively simple may vary the intermediate distance between two adjoining rows/columns.

In a further embodiment the gripper function of each gripper head may be individually controllable. With individually controllable grippers the useability options are increasing. For instance by using only a part of the grippers during picking up and/or putting down electronic components the gripper head may be used to vary to size of electronic component matrix configurations between subsequent processing steps. In practise individual control may be realised by individually controllable vacuum cups at each gripper position, but also individually controllable mechanical grippers are conceivable.

Preferably the grippers are additionally linear displaceable in a direction perpendicular to a plane determined by the gripper rows and columns. By moving the grippers in this perpendicular direction the “active” number of grippers may be varied; for instance by lowering a partial matrix of grippers that are to be used in a process step of pricking up and/or putting down electronic components while the “non-active” grippers remain is a “raised” position. Even more preferred the working position of each gripper in the perpendicular linear direction is individually controllable as such individual control of the grippers provides the maximum flexibility in bringing grippers in “activating” and “non-activating” positions. To realise such perpendicular movement of the grippers, the grippers (preferably all the grippers) may be provided with a height drive for realising the displacement in the perpendicular linear direction. To control the movement (and the stopping of the movement) of the grippers driven by height drives, the height drive may be force controllable. In case the force is to be controlled a drive may for instance be stopped when such a resistance is encountered by a gripper that an electronic component is contacted. Another advantage of a force controlled perpendicular movement of the grippers is that this may prevent damage to the grippers if a certain resistance is encountered (for example because an object is placed between a gripper and an electronic component or at an electronic component deposition position). The force control of the grippers may also (indirectly) be realised in the control of the current for steering the height drives. Examples of height drives may be selected from the group of pneumatic cylinders, hydraulic cylinders and (servo)motors. Additionally to the options of use already mentioned above the of perpendicular displaceable grippers may also be used for selection of only a part of electronic components to be gripped; e.g. electronic components rejected by a previous process quality control may be left untouched, e.g. to be disposed as waste.

The invention also provides a device for handling and varying the spacing of electronic components arranged in a matrix structure, comprising a supply for electronic components arranged in an initial matrix structure, at least one gripper head according to the present invention, a manipulator for moving the gripper head; and a discharge for handled electronic components in a modified matrix structure. With such a handling device the gripper head according to the invention may be controlled in its movements in between a pickup position (the supply) and a putting down position (the discharge) and thus enables to provide all the advantages as already explained in relation to the gripper head according to the invention, which advantages are here incorporated in relation to the handling device according to the invention by reference. Preferably the handling device comprises a controller configured for determining the position of an initial matrix of electronic components, comparing the position of the initial matrix of electronic components to a predefined reference position and controlling the manipulator and the drives based on the relative position of the initial matrix of electronic components, thus enabling a automatic transfer of electronic components during which transfer the pitch between the electronic components and/or the number of rows and columns may be modified free of choice.

The present invention also provides a method for handling and varying the spacing of electronic components arranged in a matrix structure with a gripper head according to the present invention, comprising the steps of: a) providing electronic components arranged in at least one initial matrix structure; b) orienting X rows and Y columns of grippers of the gripper head in correspondence with the arrangement of the electronic components in the at least one initial matrix structure; c) bringing at least a part of the grippers of the gripper head in contact with and gripping at least some of the electronic components arranged in the at least one initial matrix structure; d) relative displacement of the rows and columns of grippers to a modified matrix structure; and e) release of the electronic components by the grippers. With such method the pitch between matrix oriented electronic components and/or the number of rows and columns of such matrix electronic components may be modified during the transfer of the electronic components from one initial position (e.g. carrier) to a subsequent position (e.g. another carrier) with all the advantages as mentioned above. The grippers may for instance be actuated for gripping by applying a low pressure to the grippers and by release with applying an overpressure to the grippers.

### BRIEF DESCRIPTION OF THE DRAWINGS

The terms Fig., Figs., Figure, and Figures are used interchangeably to refer to the corresponding figures in the drawings.

The invention will now be elucidated with reference to the non-limitative exemplary embodiments illustrated in the following figures. Corresponding elements are denoted in the figures by corresponding reference numbers. Herein shows:

FIGS. 1A-1C perspective schematic views on a 2×3 gripper head according to the present invention, wherein the position of the grippers is varied;

FIG. 2 a perspective schematic view on a 3×3 gripper head according to the present invention;

FIG. 3 a perspective schematic view on a 3×4 gripper head according to the present invention; and

FIG. 4 a schematic view of a device for handling and varying the spacing of electronic components according to the present invention.

### DESCRIPTION OF THE INVENTION

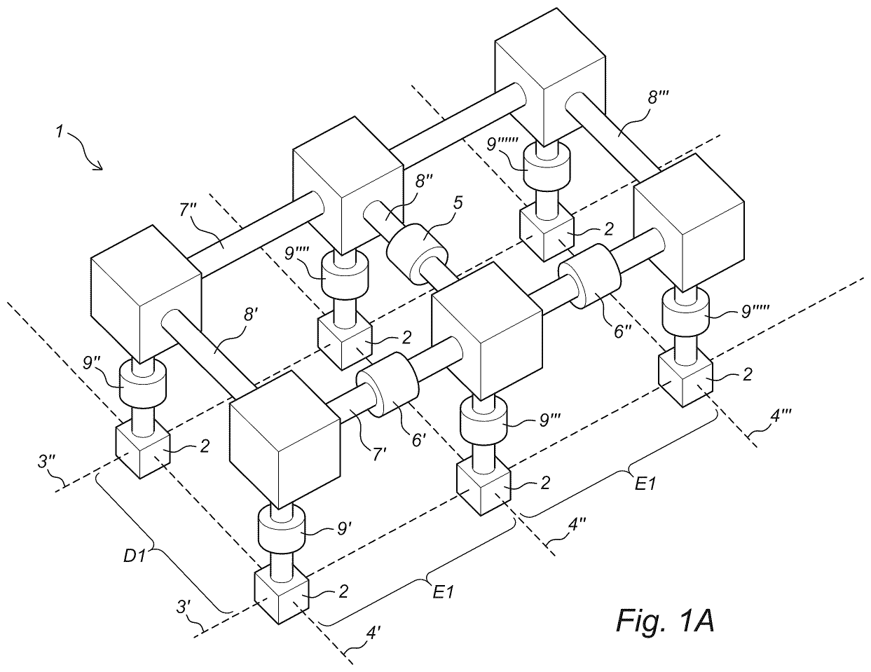

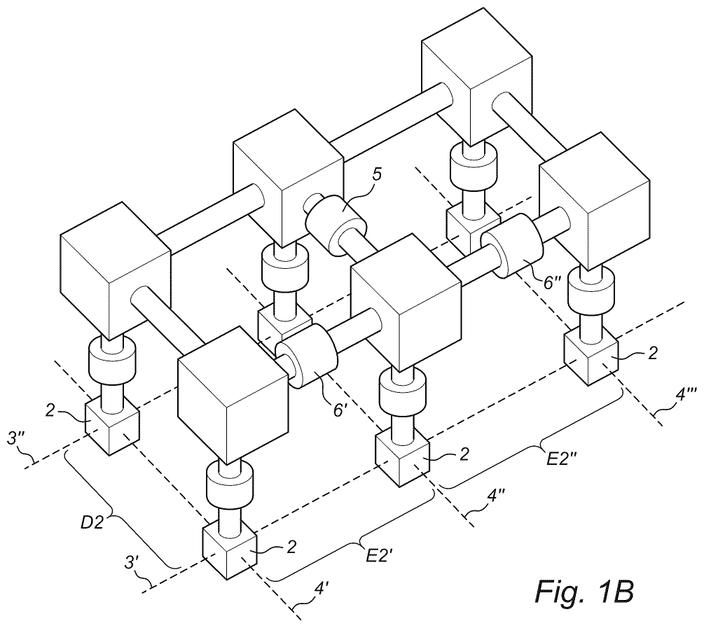

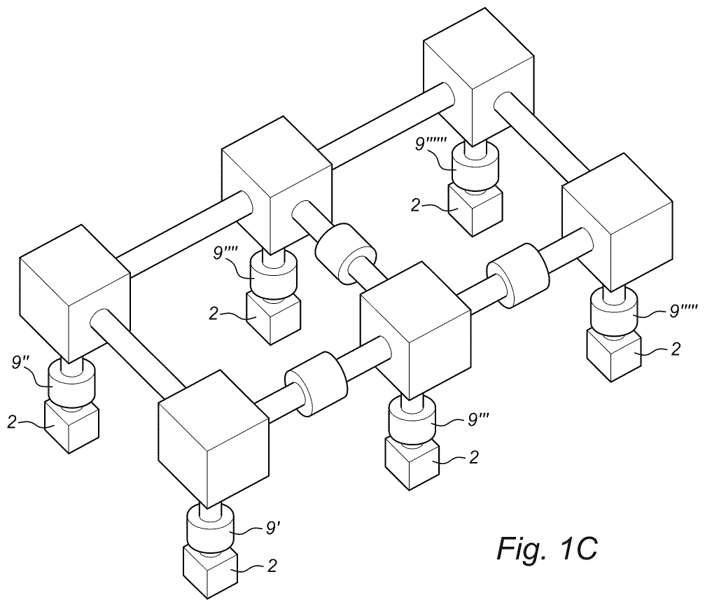

FIG. 1A shows a schematic view on a 2×3 gripper head 1, with six grippers 2 oriented in a matrix structure. The grippers 2 are oriented in two rows 3′, 3″ (with a distance D₁ between the rows 3′, 3″) and in three columns 4′, 4″. 4′″ (with a distance E₁ between the columns 4′, 4″. 4′″). Between the two rows 3′, 3″ of grippers 2 a displacement drive 5 is acting that enables to vary the distance between the two rows 3′, 3″ of grippers 2 as will be illustrated in the subsequent FIGS. 1B and 1C. Acting between the adjoining pairs of the three columns 4′, 4″. 4′″ grippers 2 two displacement drives 6′, 6″ are located to vary the distance between the respective adjoining columns 4′, 4″ and 4″, 4′″. The displacement drive 5 between the rows 3′, 3″ and the displacement drives 6′, 6″ between adjoining columns 4′, 4″. 4′″ are individually controllable. Also visible is that the grippers 2 are (slideable) attached to row guides 7′, 7″ and to (also slideable) to column guides 8′, 8″, 8′″ thus fixating a matrix structure of the grippers 2.

Furthermore is shown in FIG. 1A that the grippers 2 are also displaceable in a direction perpendicular to a plane determined by the gripper rows 3′, 3″ and columns 4′, 4″. 4′″ as the grippers are individually attached to a vertical displacement drives 9′-9″″″ that individually control the vertical position of each gripper 2. Preferably the actuation of displacement drives 9′-9″″″ is individually force controlled.

FIG. 1B shows the gripper head 1 from FIG. 1A wherein the gripper orientation is changed relative to the orientation depicted in FIG. 1A. By actuating the displacement drive 5 the gripper rows 3′, 3″ are now brought closer together so the distance D₂ between the gripper rows 3′, 3″ in this figure is less than the distance D₁ between the gripper rows 3′, 3″ in FIG. 1A. Likewise the two displacement drives 6′, 6″ between the respective gripper columns 4′, 4″ and 4″, 4′″ are actuated (in different ways) when compared to the situation depicted in FIG. 1A resulting in the distances E₂′ and E₂″ between the gripper columns 4′, 4″ and 4″, 4′″ in this figure are less than the distance E₁ between the gripper columns 4′, 4″ and 4″, 4′″ in FIG. 1A, wherein also the distances E₂ and E₂″ deviate from each other.

FIG. 1C shows the gripper head 1 from FIG. 1A wherein the gripper orientation of the gripper two rows 3′, 3″ and the gripper columns 4′, 4″, 4′″ is identical to the orientation depicted in FIG. 1A, however here the vertical position of the grippers 2 is changed relative to their position depicted in FIG. 1A. Relative to the situation depicted in FIG. 1A the vertical displacement drives 9′-9″″″ are actuated thus raising the grippers compared to the previous illustrated situation.

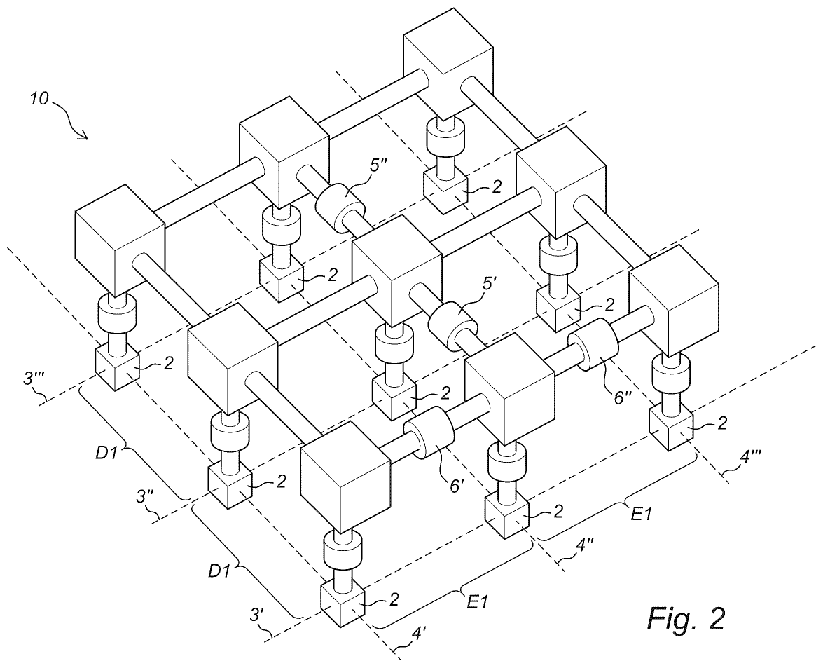

FIG. 2 shows a schematic view on a 3×3 gripper head 10, with nine grippers 2 oriented in a matrix structure. The grippers 2 are oriented in three rows 3′, 3″, 3′″ (with a distance D₁ between the rows 3′, 3″, 3′″) and in three columns 4′, 4″. 4′″ (with a distance E₁ between the columns 4′, 4″. 4′″). Between the three rows 3′, 3″, 3′″ of grippers 2 displacement drives 5′, 5″ are acting that enable to vary the distance between adjoining rows 3′, 3″ and 3″, 3′″ of grippers 2. Between the adjoining pairs of the three columns 4′, 4″ and 4″, 4′″ grippers 2 two displacement drives 6′, 6″ are acting to vary the distance between the respective adjoining columns 4′, 4″ and 4″, 4′″. The displacement drives 5″, 5″ between the rows 3′, 3″. 3″″ and the displacement drives 6′, 6″ between adjoining columns 4′, 4″. 4′″ are individually controllable. Also visible is that the grippers 2 are (slideable) attached to row guides 7′, 7″, 7′″ and to (also slideable) to column guides 8′, 8″, 8′″ thus fixating a matrix structure of the grippers 2. For a further functioning of this 3×3 gripper head 10 reference is made to the FIGS. 1A-1C wherein the changer of the distances D₁ and E₁ is explained.

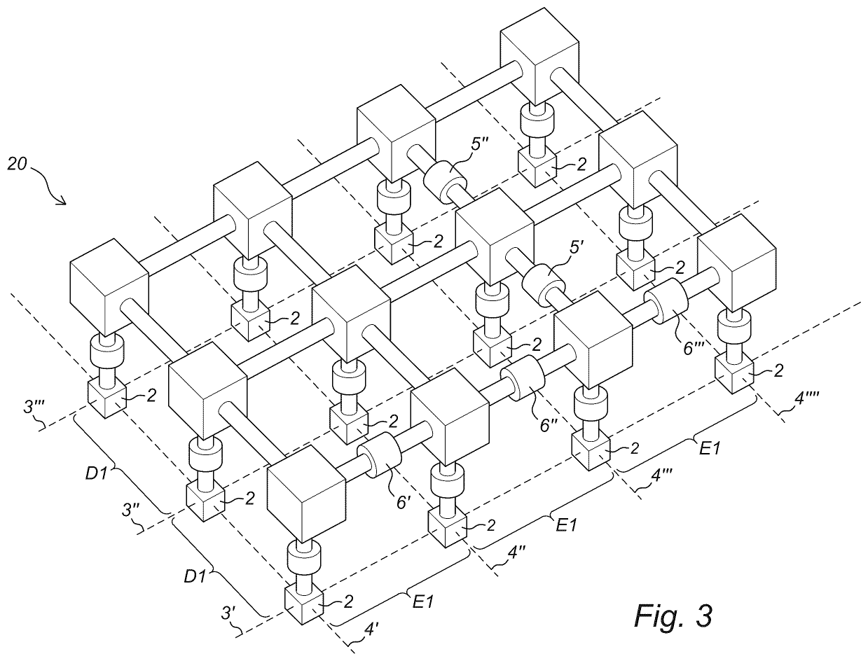

FIG. 3 shows a further embodiment of a gripper head 20 according to the present invention; here a 3×4 gripper head 20, with twelve grippers 2 oriented in a matrix structure. The grippers 2 are oriented in three rows 3′, 3″, 3″″ (with a distance D₁ between the rows 3′, 3″, 3″) and in four columns 4′, 4″, 4′″, 4″″ (with a distance E₁ between the columns 4′, 4″, 4′″, 4″″). Between the three rows 3′, 3″, 3′″ of grippers 2 displacement drives 5′, 5″ are acting that enable to vary the distance between adjoining rows 3′, 3″ and 3″, 3′″ of grippers 2. Between the adjoining pairs of the four columns 4′, 4″; 4″, 4′″ and 4′″, 4″″ grippers 2 three displacement drives 6′, 6″, 6′″ are acting to vary the distance between the respective adjoining columns 4′, 4″; 4″, 4′″. Also for a further functioning of this 3×4 gripper head 20 reference is made to the FIGS. 1A-1C wherein the changer of the distances D₁ and E₁ is explained.

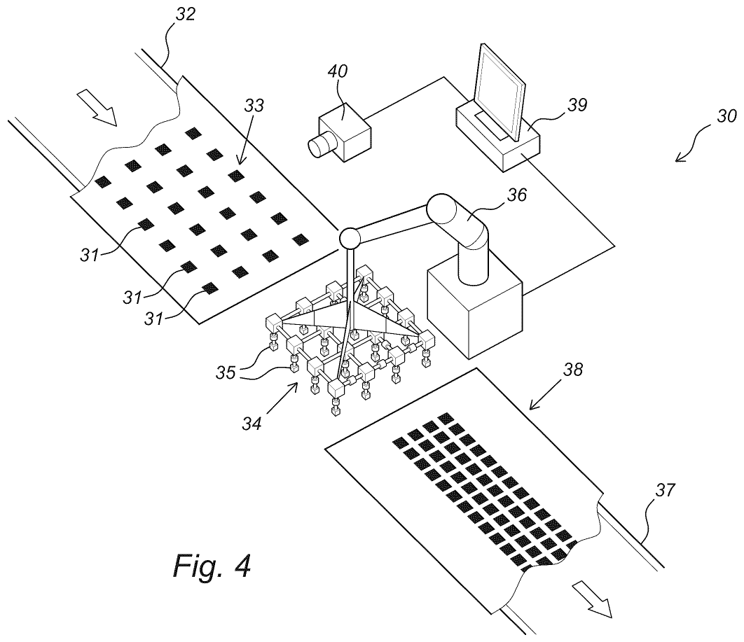

FIG. 4 schematically shows a device 30 for handling and varying the spacing of electronic components 31, comprising a feed system 32 for the electronic 31 components arranged in an initial matrix structure 33. The electronic components 31 are grabbed by a gripper head 34 with grippers 35 for example a 4x4 gripper head 34. The griper head 34 is held and manipulated by positioning means 36, here embodied as an robot arm, enabling the gripper head 34 to reach to the feed system 32 and to subsequently discharge the grasped electronic components 31 to a discharge system 37. During the transit of the electronic components 31 from the feed system 32 to the discharge system 37 the configuration of the matrix wherein the electronic components 31 are held by the gripper head 34 may be changed (see for further explanation of the working of the griper head 34 the FIGS. 1A-1C). Subsequently the electronic components 31 may be released in a single operation, or like required here in a situation wherein the electronic components 31 are changed to a modified (more compact) structure 38, in a double step or multiple step release operation. Also shown is a controller 39 that controls the gripper head 34 and the positioning means 36, based on—among others, the information received from for instance a vision system 40, and/or any other information source.

1. A gripper head for handling and varying the spacing of electronic components arranged in a matrix structure, comprising:
multiple grippers arranged in a matrix orientation of X rows of grippers, wherein X≥2, and Y columns of grippers, wherein Y≥3; and
separate displacement drives between all the adjoining gripper rows and between all the adjoining gripper columns for varying the distance between adjoining gripper rows and adjoining gripper columns;
wherein the displacement drives are individually and separately controllable enabling to vary the distances between all the adjoining rows and/or columns of grippers.

2. The gripper head according to claim 1, wherein displacement drives are acting between all adjoining gripper rows and all adjoining gripper columns for varying the distance between adjoining gripper rows and adjoining gripper columns.

3. The gripper head according to claim 1, wherein the grippers in each row are moveable mounted on individual row guides and the grippers in each column are moveable mounted on individual column guides.

4. The gripper head according to claim 3, wherein the displacement drives are attached between adjoining row guides and between adjoining columns guides.

5. The gripper head according to claim 1, wherein the gripper function of each gripper head is individually controllable.

6. The gripper head according to claim 1, wherein a gripper is provided with a vacuum cup.

7. The gripper head according to claim 1, wherein the grippers are linear displaceable in a direction perpendicular to a plane determined by the gripper rows and columns.

8. The gripper head according to claim 7, wherein the working position of each gripper in the perpendicular linear direction is individually controllable.

9. The gripper head according to claim 7, wherein grippers are provided with a height drive for realising a displacement the perpendicular linear direction.

10. The gripper head according to claim 8, wherein at least one height drive is force controllable.

11. A device for handling and varying the spacing of electronic components arranged in a matrix structure, comprising
a supply for electronic components arranged in an initial matrix structure;
at least one gripper head according claim 1;
a manipulator for moving the gripper head; and
a discharge for handled electronic components in a modified matrix structure.

12. The device according to claim 11, wherein the handling device comprises a controller configured for determining the position of an initial matrix of electronic components, comparing the position of the initial matrix of electronic components to a predefined reference position and controlling the manipulator and the drives based on the relative position of the initial matrix of electronic components.

13. A method for handling and varying the spacing of electronic components arranged in a matrix structure with a gripper head according to claim 1, comprising the steps of:
a) providing electronic components arranged in at least one initial matrix structure;
b) orienting X rows and Y columns of grippers of the gripper head in correspondence with the arrangement of the electronic components in the at least one initial matrix structure;
c) bringing at least a part of the grippers of the gripper head in contact with and gripping at least some of the electronic components arranged in the at least one initial matrix structure;
d) relative displacement of the rows and columns of grippers to a modified matrix structure; and
e) release of the electronic components by the grippers.

14. The method according to claim 13, wherein actuating the grippers by applying a low pressure to the grippers.

15. The method according to claim 13, wherein after release of the electronic components by the grippers an overpressure is applied to the grippers.
